(19) United States
(12) Patent Application Publication
(10) Pub. No.: US 2026/0045925 A1
(43) Pub. Date: Feb. 12, 2026

(54) DEVICE AND METHOD FOR RECEIVING 1-BIT AMPLITUDE-MODULATED SIGNALS

(71) Applicant: STMicroelectronics International N.V., Geneva (CH)

(72) Inventors: Mounir BOULEMNAKHER, Coublevie (FR); Franck MONTAUDON, Meylan (FR)

(73) Assignee: STMicroelectronics International N.V., Geneva (CH)

(21) Appl. No.: 19/291,218

(22) Filed: Aug. 5, 2025

(30) Foreign Application Priority Data
Aug. 8, 2024 (FR) FR2408773

(51) Int. Cl. H03F 3/45; H03K 3/037; H04B 1/06

(52) U.S. Cl. CPC H03F 3/45475; H04B 1/06; H03F 2203/45116; H03K 3/037

(57) ABSTRACT

A device receives a 1-bit amplitude-modulated input signal. The device includes a differential amplifier circuit with first and second differential inputs, wherein the first input is configured to receive the input signal and the second input is configured to receive a common-mode signal having a variable value. The device also includes a circuit for modifying the value of the common-mode signal as a function of the value of an output signal of the receiver device obtained from an output signal of the differential amplifier circuit.

### PRIORITY CLAIM

This application claims the priority benefit of French Application for Patent No. FR2408773, filed on Aug. 8, 2024, the content of which is hereby incorporated by reference in its entirety to the maximum extent allowable by law.

### TECHNICAL FIELD

This disclosure generally concerns the field of communications and telecommunications, and more particularly the reception of 1-bit amplitude-modulated signals. This particularly concerns the field of wireless communications, particularly contactless communications, for example those implemented in NFC (Near Field Communication) technology.

### BACKGROUND

1-bit amplitude modulation is used for many types of communication, such as certain wireless communications.

A contactless communication device is a device capable of exchanging information via an antenna with another contactless device, for example a reader, according to one or more contactless communication protocols.

Near-field Communication, or NFC, is a wireless connectivity technology allowing communication over a short distance, for example on the order of several tens of centimeters, between electronic devices, such as between a contactless smart card and a reader.

An NFC device, which is a contactless device, is a device compatible with NFC technology. NFC technology is an open technological platform standardized in the ISO/IEC 18092 and ISO/IEC 21481 standards, but which incorporates many already existing standards, such as the type-A and type-B protocols defined in the ISO-14443 standard, which may be communication protocols usable in NFC technology.

There exist other types of contactless devices, such as bank cards provided with contactless functions, contactless tags, contactless access cards, etc.

During transmission of information between a reader and a contactless card, the reader generates an electromagnetic field via its antenna, which is generally, according to the standards conventionally used, a sine wave having a frequency equal to 13.56 MHz. Inductive coupling between the reader and the contactless card is used to electrically power and transmit data to the contactless card due to the electromagnetic field generated by the reader.

The data transmission is achieved, for example, by using 1-bit amplitude modulation such as OOK (“On Off Keying”) modulation. Different modulations are possible, using different coding schemes (modified Miller, NRZ, Manchester, etc.), different modulation indices (from a few percent to 100%), and different signal shapes, including in particular shorter or longer rising or falling edges.

Different noise and interference phenomena may alter the shape of the received signal. For example, overshoot and undershoot phenomena may occur. Such an overshoot corresponds to a rise in the value of a received signal beyond an expected nominal value, followed by a phase of adjustment of the value of the signal until it becomes equal to the expected nominal value. An undershoot phenomenon corresponds to the same phenomenon as the overshoot but occurring in the opposite direction, that is, a drop in the value of a received signal below an expected nominal value, followed by a phase of adjustment of the value of the signal until it becomes equal to the expected nominal value.

For reasons of interoperability with different transmitting devices, a contactless device for receiving 1-bit amplitude-modulated signals must be able to operate with different types of modulation. Further, it is important for the receiver device to tolerate noise and/or interference phenomena present in the received modulated signals.

These constraints also apply to other types of devices, contactless or not, for receiving 1-bit amplitude-modulated signals.

There exists a need to provide a solution enabling addressing of the problems encountered with existing solutions.

### SUMMARY

An embodiment overcomes all or part of the disadvantages of known solutions and provides a device for receiving a 1-bit amplitude-modulated input signal, comprising at least: a differential amplifier circuit comprising first and second differential inputs, the first input being configured to receive the input signal and the second input being configured to receive a common-mode signal having a variable value; a circuit for modifying the value of the common-mode signal as a function of the value of an output signal of the receiver device obtained from an output signal of the differential amplifier circuit.

According to a specific embodiment, the differential amplifier circuit is configured as a differentiator, or derivator.

According to a specific embodiment, the differential amplifier circuit comprises at least: an operational amplifier comprising a non-inverting input forming the second input of the differential amplifier circuit; a first resistive element comprising a first electrode coupled to an inverting input of the operational amplifier; a capacitive element comprising a first electrode coupled to a second electrode of the first resistive element, and a second electrode forming the first input of the differential amplifier circuit; a second resistive element forming a feedback element coupled between an output of the operational amplifier and the inverting input of the operational amplifier.

According to a specific embodiment, the receiver device further comprises a comparator circuit configured to compare the output signal of the differential amplifier circuit with high and low threshold values, and to deliver as an output the output signal of the receiver device taking a first output value when the output signal of the differential amplifier circuit changes from a value lower than the high threshold value to a value higher than the high threshold value, and taking a second output value when the output signal of the differential amplifier circuit changes from a value higher than the low threshold value to a value lower than the low threshold value; and the circuit for modifying the value of the common-mode signal is configured to define the value of the common-mode signal at a high common-mode value when the output signal of the receiver device takes the first output value, and to define the value of the common-mode signal at a low common-mode value, lower than the high common-mode value, when the output signal of the receiver device takes the second output value.

According to a specific embodiment, the output of the comparator circuit is coupled to a control input of the circuit for modifying the value of the common-mode signal.

According to a specific embodiment, the comparator circuit comprises at least: a first comparator comprising a non-inverting input coupled to an output of the differential amplifier circuit, and an inverting input configured to receive the low threshold value; a second comparator comprising a non-inverting input coupled to the output of the differential amplifier circuit, and an inverting input configured to receive the high threshold value; a first inverter comprising an input coupled to an output of the first comparator; an RS flip-flop comprising a reset input coupled to an output of the first inverter, and a set input coupled to an output of the second comparator.

According to a specific embodiment, the comparator circuit further comprises a second inverter comprising an input coupled to an output of the RS flip-flop, and an output forming the output of the comparator circuit.

According to a specific embodiment, the comparator circuit comprises at least: a threshold value switch configured to couple a first input of the threshold value switch, to which the low threshold value is intended to be applied, to an output of the threshold value switch when the output signal of the receiver device takes the first output value, and to couple a second input of the threshold value switch, to which the high threshold value is intended to be applied, to the output of the threshold value switch when the output signal of the receiver device takes the second output value; a third comparator comprising a first input coupled to the output of the threshold value switch and a second input coupled to an output of the differential amplifier circuit.

According to a specific embodiment, the circuit for modifying the value of the common-mode signal comprises at least one first switch configured to couple a first input of the first switch, to which the high common-mode value is intended to be applied, to an output of the first switch when the output signal of the receiver device takes the first output value, and to couple a second input of the first switch, to which the low common-mode value is intended to be applied, to the output of the first switch when the output signal of the receiver device takes the second output value, and the output of the first switch is coupled to the second input of the differential amplifier circuit.

According to a specific embodiment, the circuit for modifying the value of the common-mode signal further comprises a second switch configured to couple the output of the first switch or an input of the second switch to which a common-mode signal of constant value is intended to be applied, to the second input of the differential amplifier circuit, or the circuit for modifying the value of the common-mode signal is configured to define, in a static operating mode of the value of the common-mode signal, the high and low common-mode values equal to each other.

According to a specific embodiment, a difference between the high threshold value and the low common-mode value is equal to the difference between the high common-mode value and the low threshold value.

According to a specific embodiment, the high threshold value is higher than the high common-mode value, and the low threshold value is lower than the low common-mode value.

A contactless communication device is also provided comprising at least one device for receiving a 1-bit amplitude-modulated input signal according to a specific embodiment.

A method for receiving a 1-bit amplitude-modulated input signal is also provided, comprising at least: pre-conditioning the input signal based on a difference between a common-mode signal and the input signal, delivering as an output an amplification output signal; modifying the value of the common-mode signal as a function of the value of a receive output signal obtained from the amplification output signal.

According to a specific embodiment, the pre-conditioning of the input signal comprises an amplification of a derivative of the difference between the common-mode signal and the input signal.

According to a specific embodiment, the method further comprises, between the amplification and the modification, a comparison of the amplification output signal with high and low threshold values, delivering the receive output signal taking a first output value when the amplification output signal changes from a value lower than the high threshold value to a value higher than the high threshold value, and taking a second output value when the amplification output signal changes from a value higher than the low threshold value to a value lower than the low threshold value, and the modification is implemented such that the value of the common-mode signal is equal to a high common-mode value when the receive output signal takes the first output value, and the value of the common-mode signal is equal to a low common-mode value, lower than the high common-mode value, when the receive output signal takes the second output value.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows an example of a device for receiving a 1-bit amplitude-modulated input signal, according to a specific embodiment;

FIG. 2 schematically shows examples of signals obtained in a device for receiving a 1-bit amplitude-modulated input signal, according to a specific embodiment;

FIG. 3 schematically shows examples of signals obtained in a device for receiving a 1-bit amplitude-modulated input signal in the absence of a change in the value of the common-mode signal;

FIG. 4 schematically shows an example of a contactless communication device according to a specific embodiment;

FIG. 5 schematically shows steps of a method of receiving a 1-bit amplitude-modulated input signal according to a specific embodiment;

FIG. 6 schematically shows a variant of an example of a device for receiving a 1-bit amplitude-modulated input signal, according to a specific embodiment.

### DETAILED DESCRIPTION

Like features have been designated by like references in the various figures. In particular, the structural and/or functional features that are common among the various embodiments may have the same references and may have identical structural, dimensional and material properties.

For clarity, only those steps and elements which are useful to the understanding of the described embodiments have been shown and are described in detail. In particular, the formation of the different elements and circuits (differential amplifier, comparator circuit, circuit for modifying the value of the common-mode signal, comparator, inverter, RS flip-flop, switch, etc.) of the device is not detailed. Those skilled in the art will be capable of implementing in detailed fashion the different functions of the device based on the functional description given herein.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

Unless specified otherwise, the expressions “about”, “approximately”, “substantially”, and “in the order of” signify plus or minus 10%, preferably plus or minus 5%. Further, the ranges of values given below are to be understood, without explicit indication to the contrary, as including the limits of these ranges of values.

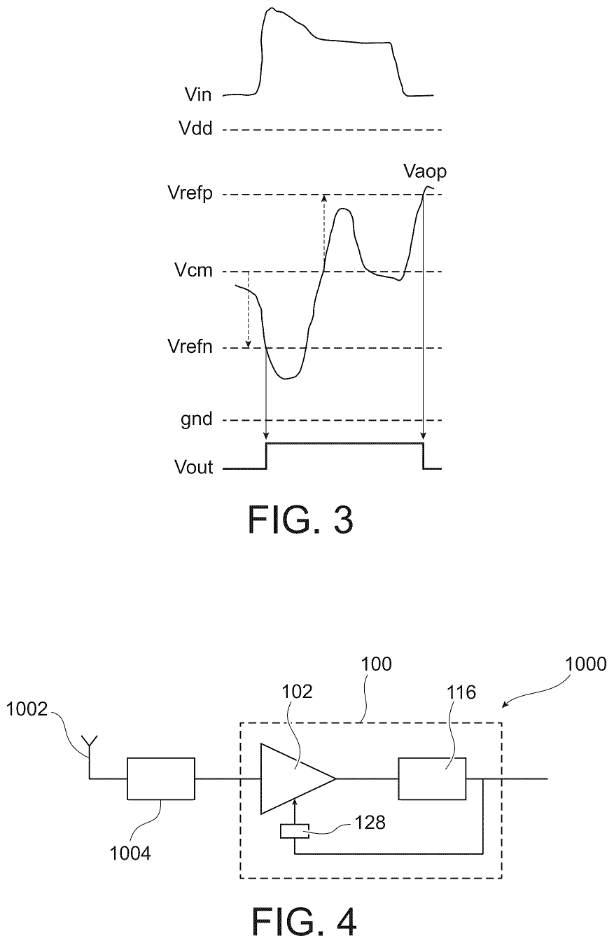

Further, the signals of the timing diagrams of FIGS. 2 and 3 are schematically shown, and out of scale with respect to one another, both for the amplitudes and for the durations of the different parts of these signals.

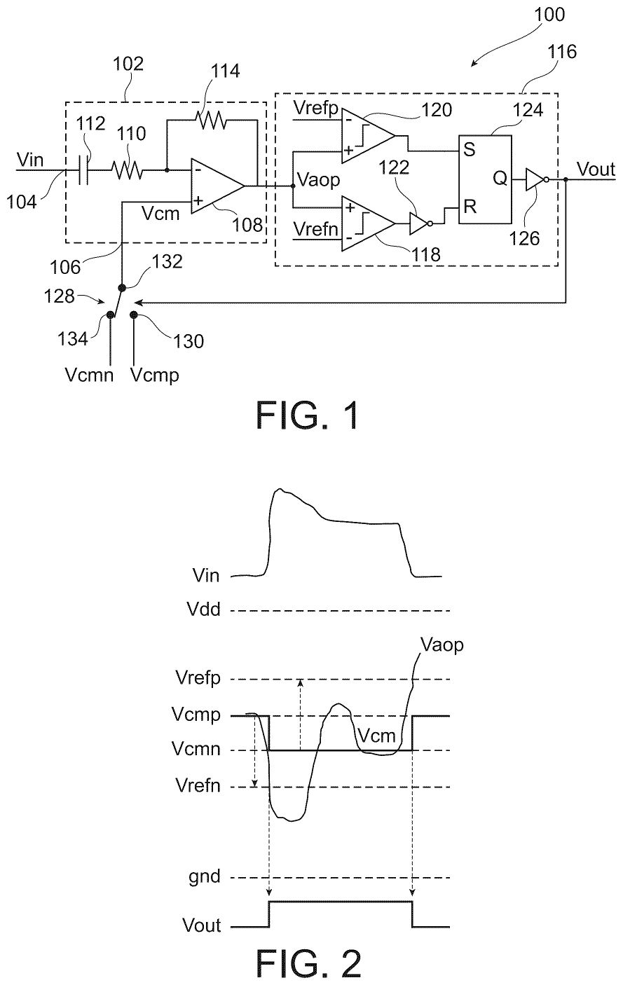

An example of a device 100 for receiving a 1-bit amplitude-modulated input signal according to a specific embodiment is described hereafter in relation to FIG. 1.

Device 100 comprises a differential amplifier circuit 102. Circuit 102 comprises first and second differential inputs 104, 106. The first input 104 is configured to receive the 1-bit amplitude-modulated input signal, referred to as Vin in FIG. 1. The second input 106 is configured to receive a common-mode signal, referred to as Vcm in FIG. 1. Input signal Vin is for example modulated according to an OOK modulation or another type of 1-bit ASK (Amplitude Shift Keying) modulation.

In the example of FIG. 1, circuit 102 is configured as a differentiator, or derivator. Circuit 102 comprises, in this example, an operational amplifier 108 comprising a non-inverting input forming the second input 106 and to which common-mode signal Vcm is applied. In this example, circuit 102 further comprises a first resistive element 110, for example a resistor, comprising a first electrode coupled to an inverting input of operational amplifier 108 and a second electrode coupled to a first electrode of a capacitive element 112, for example a capacitor. A second electrode of capacitive element 112 forms the first input 104 of circuit 102. In this example, circuit 102 further comprises a second resistive element 114, for example a resistor, forming a feedback element coupled between an output of operational amplifier 108, which forms an output of circuit 102, and its inverting input.

In the described example embodiment, circuit 102 thus delivers an output signal, called Vaop in FIG. 1, having an amplitude proportional to the derivative of difference Vcm−Vin.

In the example of FIG. 1, device 100 further comprises a comparator circuit 116 configured to compare the output signal Vaop of circuit 102 with high and low threshold values, respectively called Vrefp and Vrefn in FIG. 1, and to deliver an output signal, called Vout in FIG. 1, taking a first output value, for example corresponding to a logic ‘0’, when the value of output signal Vaop changes from a value lower than high threshold value Vrefp to a value higher than high threshold value Vrefp. Further, output signal Vout takes a second output value, corresponding for example to a logic ‘1’, when the value of output signal Vaop changes from a value higher than low threshold value Vrefn to a value lower than low threshold value Vrefn. The output signal Vout delivered by circuit 116 corresponds to the output signal of device 100.

In the example of FIG. 1, circuit 116 comprises a first comparator 118 comprising a non-inverting input coupled to the output of circuit 102 to which signal Vaop is delivered, and an inverting input configured to receive low threshold value Vrefn. In this example, circuit 116 also comprises a second comparator 120 comprising a non-inverting input coupled to the output of circuit 102 and an inverting input configured to receive high threshold value Vrefp. In this example, circuit 116 also comprises a first inverter 122 comprising an input coupled to an output of the first comparator 118. Further, in this example, circuit 116 comprises an RS flip-flop 124 comprising a reset input coupled to an output of first inverter 122, and a set input coupled to an output of second comparator 120. Finally, in this example, circuit 116 comprises a second inverter 126 comprising an input coupled to an output of RS flip-flop 124, and an output forming an output of circuit 116 to which signal Vout is delivered.

In this example, circuit 116 implements an analog-to-digital conversion of the signal delivered at the output of circuit 102, with, as the threshold for the change of value of signal Vout, the low and high threshold values Vrefn and Vrefp.

Device 100 also comprises a circuit 128 for modifying the value of common-mode signal Vcm as a function of the value of output signal Vout. Circuit 128 is configured to define the value of this signal Vcm at a high common-mode value, referred to as Vcmp in FIG. 1, when output signal Vout takes the first output value. Circuit 128 is also configured to define the value of signal Vcm at a low common-mode value Vcmn, lower than the high common-mode value Vcmp in FIG. 1, when output signal Vout takes the second output value.

In the described example embodiment, the output of circuit 116 is coupled to a control input of circuit 128, such that circuit 128 forms part of a feedback loop of device 100. In the example of FIG. 1, circuit 128 comprises a switch, for example of CMOS type. This switch is configured to couple a first input 130, to which high common-mode value Vcmp is applied, to an output 132 of the switch when output signal Vout takes the first output value, and to couple a second input 134, to which low common-mode value Vcmn is applied, to output 132 when output signal Vout takes the second output value. In this example, the output 132 of the switch is coupled to the second input 106 of circuit 102.

In the example of FIG. 1, all signals Vin, Vcm, Vaop, Vrefp, Vrefn, Vout, Vcmp, and Vcmn correspond to voltages.

As a variant of the above-described example, at least one of circuits 102, 116, and 128 may be formed with components different from those described in the above examples.

The operation of the device 100 described above is explained hereafter in relation to FIG. 2 showing signals obtained in device 100.

In the example of FIG. 2, the input signal Vin received by device 100 comprises a first switching from a low state (logic ‘0’) to a high state (logic ‘1’), a holding of the high state for a given time period, then a switching from the high state to the low state. In this example, signal Vin exhibits, during the switching from the low state to the high state, an overshoot generating, for a short time, an exceeding of the value corresponding to the high state and then a return to the nominal value of the high state.

In this example, as long as input signal Vin remains in the low state, the value of common-mode signal Vcm is equal to high common-mode value Vcmp, and the value of signal Vaop obtained at the output of circuit 102 is equal to or close to value Vcmp. Output signal Vout remains in the low state.

When input signal Vin increases to transit to the high state, the value of signal Vaop falls, and when it becomes lower than value Vrefn, the value of signal Vout transits to the high state, which also causes, through circuit 128, the change of the value of the common-mode signal, which becomes equal to low common-mode value Vcmn.

When the value of input signal Vin decreases to return to the nominal value of the high state, due to the overshoot phenomenon occurring on signal Vin, the value of signal Vaop rises back. However, given that the value of signal Vaop does not exceed, during the decrease in the value of input signal Vin, high threshold value Vrefp, the value of signal Vout remains in the high state. When the value of Vin is stabilized at the nominal value of the high state, the value of signal Vaop is equal to or close to value Vcmn.

When input signal Vin decreases to transit to the low state, the value of signal Vaop increases and when it becomes higher than value Vrefp, the value of signal Vout switches to the low state, which also causes, through circuit 128, the change of the value of the common-mode signal which becomes equal to high common-mode value Vcmp.

Thus, in device 100, the value of common-mode signal Vcm is dynamic and is determined as a function of the value of output signal Vout, and thus of the value of the data received by device 100.

The use of high and low threshold values Vrefp, Vrefn, different from each other, forms a hysteresis in the operation of device 100 so that only significant changes of value of Vin, that is, the values of the transmitted data, are reflected in output signal Vout, and not variations due to noise and to interference phenomena.

Further, in device 100, the difference between values Vcmn and Vrefp forms a tolerance interval for an upward variation of the value of signal Vaop, and thus a tolerance interval for a downward variation of the value of signal Vin, within which these signals can vary without generating a change in the value of signal Vout. This tolerance interval is useful in particular when signal Vin is subject to overshoot phenomena, as described in the example of FIG. 2.

Similarly, the difference between values Vcmp and Vrefn forms a tolerance interval for a downward variation of the value of signal Vaop, and thus a tolerance interval for an upward variation of the value of signal Vin, within which these signals can vary without generating a change in the value of signal Vout. This tolerance interval is useful in particular when signal Vin is subject to undershoot phenomena, that is, when the value of signal Vin falls, for a short time, to a value lower than that corresponding to the low state, and then returns to the nominal value of the low state.

In device 100, due to the fact that the value of common-mode signal Vcm varies and transits to a high common-mode value Vcmp when the value of the output signal Vaop of circuit 102 rises above high threshold value Vrefp, and transits to a low common-mode value Vcmn which is lower than high common-mode value Vcmp, when the value of Vaop falls below low threshold value Vrefn, it is possible to have low and high threshold values Vrefn, Vrefp which are closer to each other than if the value of common-mode signal Vcm was constant, for given intervals of tolerance to the variation of the value of Vaop. Thus, a smaller difference between values Vrefn and Vrefp allows, for a given tolerance to the different variations of signal Vin, an operation of device 100 with a lower power supply voltage, due to the fact that value Vrefp is lower than or equal to a high power supply potential Vdd and that value Vrefn is higher than or equal to a low power supply potential Gnd, for example corresponding to ground. Further, for a given difference between values Vrefn and Vrefp, the variation of the value of common-mode signal Vcm such as implemented by device 100 enables having a greater tolerance to the different variations of signal Vin.

For example, difference Vcmp−Vcmn may be in the range from approximately 100 mV to 200 mV.

Device 100 enables facilitating the compromise between a difference Vrefp−Vrefn which must be large to obtain good tolerance to noise and overshoot/undershoot phenomena, and sufficient amplification gain and linearity with a relatively low power supply voltage. The use of the common-mode signal of variable value enables decreasing the operating dynamics of differential amplifier circuit 102 and of comparator circuit 116 without having to decrease the tolerance intervals corresponding to the differences between the high and low threshold values Vrefp, Vrefn, and the value of common-mode signal Vcm in order to have good robustness against possible parasitic variations of input signal Vin. The use of a common-mode signal Vcm of variable value also enables, as compared with a receiver device using a common-mode signal of fixed or constant value, decreasing the power supply voltage of device 100 without impacting the constraints linked to the tolerance intervals for the variations of input signal Vin.

As a comparison, FIG. 3 shows signals similar to those previously described in relation to FIG. 2 and obtained in a device for receiving a 1-bit amplitude-modulated input signal in which the value of common-mode signal Vcm is constant. To obtain the same tolerances to overshoot and undershoot variations as in device 100, it is necessary to have a difference between values Vrefn and Vrefp which is greater than in device 100, that is, greater operating dynamics of the amplification circuit.

In the previously-described example of device 100, the difference between high threshold value Vrefp and low common-mode value Vcmn is equal to the difference between high common-mode value Vcmp and low threshold value Vrefn. This results in tolerance intervals for overshoot and undershoot phenomena which are similar. As a variant, it is possible to have tolerance intervals for these phenomena which are not similar or identical to each other, and thus to have a difference between high threshold value Vrefp and low common-mode value Vcmn which is not equal to that between high common-mode value Vcmp and low threshold value Vrefn.

In the previously-described example of device 100, high threshold value Vrefp is higher than high common-mode value Vcmp, and low threshold value Vrefn is lower than low common-mode value Vcmn. As a variant, according to the desired tolerance intervals, it is possible to have high threshold value Vrefp which is lower than or equal to high common-mode value Vcmp, and/or to have low threshold value Vrefn which is higher than or equal to low common-mode value Vcmn, by having low threshold value Vrefn which is lower than high common-mode value Vcmp, and high threshold value Vrefp which is higher than the low common-mode value Vcmn.

According to an alternative embodiment shown in FIG. 6, circuit 116 may comprise a single comparator 136, for example called third comparator, configured to compare signal Vaop with one or the other of the high and low threshold values Vrefp, Vrefn, according to the value of signal Vout. In this case, circuit 116 comprises an additional device 138, for example a switch called threshold value switch, to switch and apply to the input of this single comparator 136 the desired threshold value as a function of the value of Vout. In the described example, threshold value switch 138 is configured to couple a first input 140 of threshold value switch 138, to which low threshold value Vrefn is intended to be applied, to an output 142 of threshold value switch 138 when output signal Vout takes the first output value, and to couple a second input 144 of threshold value switch 138, to which high threshold value Vrefp is intended to be applied, to the output 142 of threshold value switch 138 when output signal Vout takes the second output value. Further, in the example of FIG. 6, a first input of the third comparator 136 (the non-inverting input in FIG. 6) is coupled to the output 142 of threshold value switch 138, and a second input of the third comparator 136 (the inverting input in FIG. 6) is coupled to the output of differential amplifier circuit 102.

According to another alternative embodiment, circuit 128 may comprise a second switch enabling applying to the second input 106 of circuit 102 either the common-mode signal Vcm of variable value such as previously described, or a common-mode signal of fixed value, that is, having a value constant whatever the value of signal Vout. Such a variant enables having compatibility with environments where the common-mode voltage is not dynamic. For example, a common-mode signal of fixed value may be used for communication standards where overshoot or undershoot phenomena are less prevalent, for example, the data transmission speed is higher.

As an alternative, an operating mode with a common-mode signal of fixed value may be obtained by forming circuit 128 such that it is configured to define, when device 100 enters this operating mode, low common-mode value Vcmn as being equal to high common-mode value Vcmp.

The variants and alternatives described above are compatible with one another and may be combined.

Device 100 is advantageously used within a contactless communication device 1000 such as shown, for example, in FIG. 4. In this example, device 100 forms part of the receive chain of device 1000. In addition to device 100, device 1000 also comprises an antenna 1002 configured to receive an input electromagnetic field, and a signal extraction circuit 1004 configured to deliver as an output signal Vin based on the signal delivered by antenna 1002.

Device 1000 may include other components not described herein.

According to a specific example embodiment, device 1000 is of NFC type and may be configured to receive data via an electromagnetic field having a frequency equal to 13.56 MHz.

When device 100 is used during reception of signals within a contactless communication device such as device 1000, the performed change in the value of common-mode signal Vcm allows greater tolerance to variations in the electromagnetic field shapes used for data transmission, and enables having better interoperability of device 1000 with other contactless communication devices and/or lower power consumption of device 100, which forms the demodulator of device 1000. When device 1000 is intended to be electrically powered by the electromagnetic field received and transmitting the data, for example when device 1000 corresponds to a contactless card, the fact that device 1000 can operate with a lower power supply voltage also means that device 1000 can operate with weaker electromagnetic fields, thus decreasing this constraint on the device transmitting the data.

Device 1000 may correspond to a contactless communication device, for example a contactless bank card, an NFC device, a contactless tag, a contactless access card, etc. Device 1000 may be compatible with a plurality of different types of readers.

In the previously-described example, device 1000 corresponds to a contactless communication device in which the received electromagnetic field is used for data transmission and for the powering of device 1000. For example, device 100 may be configured to communicate with a reader emitting the received electromagnetic field. Device 1000 may be configured to implement a passive load modulation (PLM).

As a variant, device 1000 may comprise its own power supply. For example, device 100 may correspond to a device emulated in card emulation mode (or CE) such as a cell phone or a connected object.

As a variant, device 100 may be used for the demodulation of signals other than data transmitted in contactless fashion. In this case, device 100 may be used in a communication device 1000 other than a contactless device.

Device 100 may be used for any conversion of an analog signal into a 1-bit digital signal (sensor, etc.).

Generally, it is provided to implement a method of receiving a 1-bit amplitude-modulated input signal Vin, comprising at least: amplification of a derivative of a difference between a common-mode signal Vcm and input signal Vin, delivering as an output an amplification output signal Vaop; modification of the value of common-mode signal Vcm as a function of the value of a receive output signal Vout obtained from amplification output signal Vaop.

In the previously-described examples, the amplification function is implemented by a differentiator, or derivator. As a variant, the amplification may be implemented without this derivative function.

It is also provided to implement a method of receiving a 1-bit amplitude-modulated input signal Vin, comprising at least: pre-conditioning, or pre-processing, of input signal Vin, based on a difference between a common-mode signal Vcm and input signal Vin, delivering as an output an amplification output signal Vaop; modification of the value of common-mode signal Vcm as a function of the value of a receive output signal Vout obtained from amplification output signal Vaop.

In such a method, the pre-conditioning of the input signal may comprise an amplification of a derivative of the difference between the common-mode signal and the input signal.

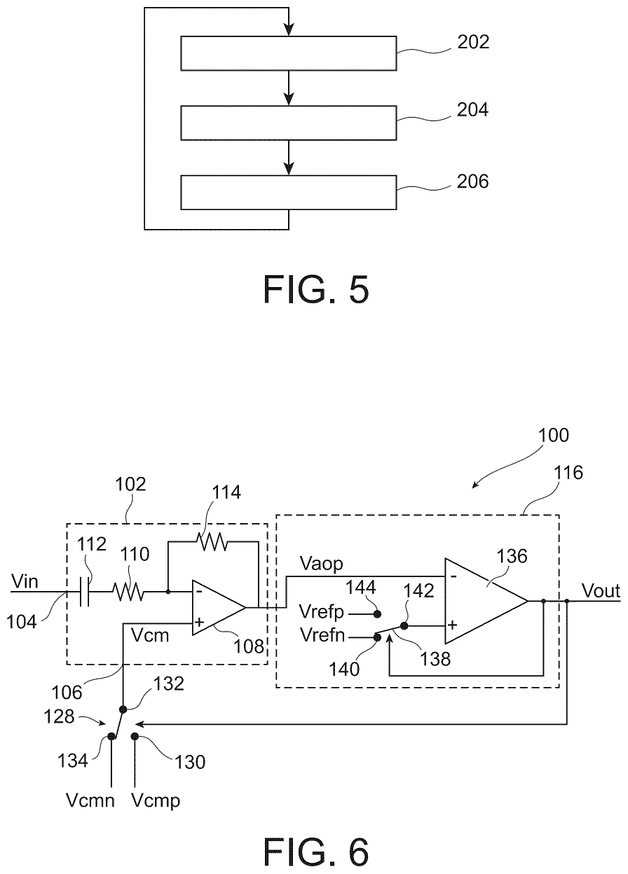

FIG. 5 shows steps of an example of a receive method, comprising at least: amplification of a derivative of a difference between common-mode signal Vcm and input signal Vin, delivering amplification output signal Vaop (step 202); comparison of amplification output signal Vaop with high and low threshold values Vrefp, Vrefn, delivering receive output signal Vout taking a first output value when amplification output signal Vaop changes from a value lower than high threshold value Vrefp to a value higher than high threshold value Vrefp, and taking a second output value when amplification output signal Vaop changes from a value higher than low threshold value Vrefn to a value lower than low threshold value Vrefn (step 204); modification of common-mode signal value Vcm such that it is equal to a high common-mode value Vcmp when receive output signal Vout takes the first output value, and that it is equal to a low common-mode value Vcmn, lower than high common-mode value Vcmp, when receive output signal Vout takes the second output value (step 206).

These steps are repeated in a loop throughout the reception of input signal Vin.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given above.

1. A receiver device, comprising:
a differential amplifier circuit comprising a first differential input configured to receive a 1-bit amplitude-modulated input signal and a second differential input configured to receive a common-mode signal having a value that is variable;
a circuit configured to modify the value of the common-mode signal as a function of a value of an output signal of the receiver device obtained from an output signal of the differential amplifier circuit; and
a comparator circuit configured to compare the output signal of the differential amplifier circuit with a high threshold value and a low threshold value, and to generate the output signal of the receiver device as having a first output value when the value of the output signal of the differential amplifier circuit changes from a value lower than the high threshold value to a value higher than the high threshold value, and as having a second output value when the value of the output signal of the differential amplifier circuit changes from a value higher than the low threshold value to a value lower than the low threshold value;
wherein the circuit configured to modify the value of the common-mode signal is configured to define the value of the common-mode signal at a high common-mode value when the output signal of the receiver device has the first output value, and to define the value of the common-mode signal at a low common-mode value, lower than the high common-mode value, when the output signal of the receiver device has the second output value.

2. The receiver device according to claim 1, wherein the differential amplifier circuit is configured as a differentiator.

3. The receiver device according to claim 2, wherein the differential amplifier circuit comprises:
an operational amplifier comprising a non-inverting input forming the second differential input of the differential amplifier circuit;
a first resistive element comprising a first electrode coupled to an inverting input of the operational amplifier;
a capacitive element comprising a first electrode coupled to a second electrode of the first resistive element, and a second electrode forming the first differential input of the differential amplifier circuit; and
a second resistive element forming a feedback element coupled between an output of the operational amplifier and the inverting input of the operational amplifier.

4. The receiver device according to claim 1, wherein the output of the comparator circuit is coupled to a control input of the circuit configured to modify the value of the common-mode signal.

5. The receiver device according to claim 1, wherein the comparator circuit comprises:
a first comparator comprising a non-inverting input coupled to an output of the differential amplifier circuit, and an inverting input configured to receive the low threshold value;
a second comparator comprising a non-inverting input coupled to the output of the differential amplifier circuit, and an inverting input configured to receive the high threshold value;
a first inverter having an input coupled to an output of the first comparator; and
an RS flip-flop comprising a reset input coupled to an output of the first inverter, and a set input coupled to an output of the second comparator.

6. The receiver device according to claim 5, wherein the comparator circuit further comprises a second inverter comprising an input coupled to an output of the RS flip-flop, and an output forming the output of the comparator circuit.

7. The receiver device according to claim 1, wherein the comparator circuit comprises:
a threshold value switch configured to couple a first input of the threshold value switch, to which the low threshold value is intended to be applied, to an output of the threshold value switch when the output signal of the receiver device has the first output value, and to couple a second input of the threshold value switch, to which the high threshold value is intended to be applied, to the output of the threshold value switch when the output signal of the receiver device has the second output value; and
a third comparator comprising a first input coupled to the output of the threshold value switch and a second input coupled to an output of the differential amplifier circuit.

8. The receiver device according to claim 1, wherein the circuit configured to modify the value of the common-mode signal comprises a first switch configured to couple a first input of the first switch, to which the high common-mode value is intended to be applied, to an output of the first switch when the output signal of the receiver device has the first output value, and to couple a second input of the first switch, to which the low common-mode value is intended to be applied, to the output of the first switch when the output signal of the receiver device has the second output value, and wherein the output of the first switch is coupled to the second input of the differential amplifier circuit.

9. The receiver device according to claim 8, wherein the circuit configured to modify the value of the common-mode signal further comprises a second switch configured to couple the output of the first switch or an input of the second switch to which a common-mode signal of constant value is intended to be applied, to the second input of the differential amplifier circuit, or wherein the circuit configured to modify the value of the common-mode signal is configured to define, in a static operating mode of the value of the common-mode signal, the high common-mode value and the low common-mode value equal to each other.

10. The receiver device according to claim 1, wherein a difference between the high threshold value and the low common-mode value is equal to a difference between the high common-mode value and the low threshold value.

11. The receiver device according to claim 1, wherein the high threshold value is higher than the high common-mode value, and the low threshold value is lower than the low common-mode value.

12. A contactless communication device, comprising at least one receiver device according to claim 1.

13. A method, comprising:
pre-conditioning a 1-bit amplitude-modulated input signal based on a difference between a common-mode signal and the 1-bit amplitude-modulated input signal, and delivering as an output an amplification output signal;
modifying a value of the common-mode signal as a function of a value of a receive output signal obtained from the amplification output signal; and
comparing the amplification output signal with a high threshold value and a low threshold value, generating the receive output signal as having a first output value when a value of the amplification output signal changes from a value lower than the high threshold value to a value higher than the high threshold value, and having a second output value when the value of the amplification output signal changes from a value higher than the low threshold value to a value lower than the low threshold value;
wherein modifying comprises setting the value of the common-mode signal equal to a high common-mode value when the receive output signal has the first output value, and setting the value of the common-mode signal equal to a low common-mode value, lower than the high common-mode value, when the receive output signal has the second output value.

14. The method according to claim 13, wherein pre-conditioning comprises amplifying a derivative of the difference between the common-mode signal and the 1-bit amplitude-modulated input signal.

15. The method according to claim 13, further comprising configuring the modifying to operate in a dynamic mode where the common-mode signal varies between the high and low common-mode values.

16. The method according to claim 13, further comprising configuring the modifying to operate in a static mode where the common-mode signal maintains a constant value.

17. The method according to claim 16, wherein in the static mode, the high common-mode value and the low common-mode value are set equal to each other.

18. The method according to claim 13, wherein a difference between the high threshold value and the low common-mode value is equal to a difference between the high common-mode value and the low threshold value.

19. A receiver device, comprising:
a differential amplifier circuit having a first input configured to receive a 1-bit amplitude-modulated input signal and a second input configured to receive a common-mode signal;
a comparator circuit configured to compare an output signal of the differential amplifier circuit with a high threshold value and a low threshold value, and to generate an output signal of the receiver device that transitions to a first value when the output signal of the differential amplifier circuit rises above the high threshold value and transitions to a second value when the output signal of the differential amplifier circuit falls below the low threshold value; and
a common-mode control circuit configured to set the common-mode signal to a high common-mode value when the output signal of the receiver device has the first value and to set the common-mode signal to a low common-mode value when the output signal of the receiver device has the second value, wherein the low common-mode value is lower than the high common-mode value.

20. The receiver device according to claim 19, wherein the differential amplifier circuit is configured as a differentiator that generates an output signal proportional to a derivative of a difference between the common-mode signal and the 1-bit amplitude-modulated input signal.

21. The receiver device according to claim 20, wherein the differential amplifier circuit comprises:
an operational amplifier having a non-inverting input forming the second input of the differential amplifier circuit;
a resistor coupled between an inverting input of the operational amplifier and a first terminal of a capacitor;
the capacitor having a second terminal forming the first input of the differential amplifier circuit; and
a feedback resistor coupled between an output of the operational amplifier and the inverting input of the operational amplifier.

22. The receiver device according to claim 19, wherein the comparator circuit comprises:
a first comparator having inputs configured to compare the output signal of the differential amplifier circuit with the low threshold value;
a second comparator having inputs configured to compare the output signal of the differential amplifier circuit with the high threshold value; and
logic circuitry configured to generate the output signal of the receiver device based on outputs of the first and second comparators.

23. The receiver device according to claim 22, wherein the logic circuitry comprises a flip-flop having a set input coupled to an output of the second comparator and a reset input coupled to an output of the first comparator through an inverter.

24. The receiver device according to claim 19, wherein the common-mode control circuit comprises a switch having:
a first input configured to receive the high common-mode value;
a second input configured to receive the low common-mode value;
an output coupled to the second input of the differential amplifier circuit; and
a control input coupled to receive the output signal of the receiver device.

25. The receiver device according to claim 19, wherein the high threshold value is greater than the high common-mode value and the low threshold value is less than the low common-mode value.

26. The receiver device according to claim 19, wherein a difference between the high threshold value and the low common-mode value equals a difference between the high common-mode value and the low threshold value.
